(19) United States
(12) Patent Application Publication
(10) Pub. No.: US 2019/0041757 A1
(43) Pub. Date: Feb. 7, 2019

(54) SURFACE TREATMENT COMPOSITION AND SURFACE TREATMENT METHOD OF RESIST PATTERN USING THE SAME

(71) Applicant: AZ Electronic Materials (Luxembourg) S.a.r.l., Luxembourg (LU)

(72) Inventors: Xiaowei WANG, Iwata-Shi (JP); Tatsuro NAGAHARA, Kakegawa-shi (JP)

(21) Appl. No.: 16/074,843

(22) PCT Filed: Jan. 25, 2017
(86) PCT No.: PCT/EP2017/000083

§ 371 Date: Aug. 2, 2018

(30) Foreign Application Priority Data
Feb. 4, 2016 (JP) 2016-020151

(51) Int. Cl. G03F 7/40

(52) U.S. Cl. CPC G03F 7/405; G03F 7/265

(57) ABSTRACT

[Problem] To provide a surface treatment composition having excellent coating properties and also having capabilities of improving heat resistance of a resist pattern and of making a resist pattern less soluble in a solvent; a resist pattern-surface treatment method using the composition; and a resist pattern formation method using the composition. [Solution] The present invention provides a surface treatment composition comprising a solvent and a polysiloxane compound soluble in the solvent. A silicon atom which is constituent atom of the polysiloxane connects to a nitrogen-substituted hydrocarbon group provided that the silicon atom directly binds to a carbon atom in the hydrocarbon group. The invention also provides a resist pattern-surface treatment method using the composition and a resist pattern formation method using the composition.

### TECHNICAL FIELD

The present invention relates to a surface treatment composition and a surface treatment method of resist pattern using the composition.

### BACKGROUND ART

In extensive fields including the manufacture of semiconductor integrated circuits such as LSIs, the preparation of FPD screens, and the production of circuit boards for color filters, thermal heads and the like, photolithographic technologies have hitherto been adopted for microdevice production or for microfabrication. Specifically, the photo-lithographic technologies are used to produce resist patterns, which are generally employed as etching masks and the like.

Recently, it has been required to improve etching resistance of resist patterns. Further, in a double patterning process, it is also required for the first resist pattern to be less soluble in an organic solvent contained in a resist composition for forming the second resist pattern.

In order to meet the requirements, there is proposed a method (freezing treatment) in which a formed resist pattern is chemically or physically treated to modify the surface thereof. Actually, various processes are proposed for the freezing treatment. For example, Patent documents 1 and 2 disclose freezing treatment processes employing silicon-containing polymers. However, they are silent about details, such as, the polymer structures, and hence it is unclear what kind of the silicon-containing polymers can effectively work.

### PRIOR ART DOCUMENTS

### Patent Documents

[Patent document 1] U.S. Patent Application Publication No. 2006/0281030, [Patent document 2] U.S. Patent Application Publication No. 2007/0048675

### DISCLOSURE OF INVENTION

### Problem to be Solved by the Invention

It is an object to provide a surface treatment composition which can improve heat resistance of a resist pattern, which can make a resist pattern less soluble in a solvent and which has excellent coating properties. Further, it is another object to provide a resist pattern surface treatment method using the composition and also to provide a resist pattern formation method using the composition.

### Means for Solving Problem

The surface treatment composition according to the present invention comprises a solvent and a polysiloxane compound soluble in said solvent, wherein a silicon atom which is constituent atom of said polysiloxane connects to a nitrogen-substituted hydrocarbon group provided that said silicon atom directly binds to a carbon atom in said hydrocarbon group.

Also, the surface treatment method according to the present invention for a resist pattern comprises the step of bringing the surface of a developed resist pattern into contact with the above composition.

Further, the resist pattern formation method according to the present invention comprises the steps of:
coating a substrate with a resist composition, to form a resist
composition layer;
exposing said resist composition layer to light;
developing the exposed resist composition layer with a developer, to form a resist pattern;
bringing the surface of said resist pattern into contact with the above composition, to form a covering layer; and
removing an excess of said composition by washing treatment.

### Effect of the Invention

The present invention makes it possible to improve heat resistance of a resist pattern and at the same time to lower solubility thereof in a solvent. Specifically, the present invention provides a surface treatment composition which has excellent coating properties and by use of which a resist pattern outstanding in heat resistance and in solvent resistance can be formed according to an easy method.

### DETAILED DESCRIPTION

surface treatment composition

The surface treatment composition (hereinafter, often simply referred to as “composition”) of the present invention comprises a solvent and a polysiloxane compound soluble in the solvent. Each component of the composition is explained as follows.

(A) polysiloxane compound

The polysiloxane compound used in the present invention is characterized in that a silicon atom contained therein connects to a hydrocarbon group having a nitrogen-containing substituent provided that the silicon atom directly binds to a carbon atom in the hydrocarbon group.

Polysiloxane is a polymer comprising Si—O—Si bonds, and the polysiloxane compound in the present invention is an organic polysiloxane having a particular organic substitutent described above. The polysiloxane compound generally also has a silanol or alkoxysilyl group, as well as a nitrogen-substituted hydrocarbon group. Here, “a silanol or alkoxysilyl group” means a hydroxyl or alkoxy group that binds directly to a silicon atom constituting a siloxane skeleton.

There are no particular restrictions on the main chain structure of the polysiloxane used in the present invention, and hence it can be freely selected according to the purpose. On the basis of the number of oxygen atoms connecting to a silicon atom, the skeleton structure of polysiloxane can be generally categorized into three types: that is, silicone skeleton (in which two oxygen atoms connect to a silicon atom), silsesquioxane skeleton (in which three oxygen atoms connect to a silicon atom), and silica skeleton (in which four oxygen atoms connect to a silicon atom). In the present invention, silicone skeleton or silsesquioxane skeleton is preferred. The polysiloxane compound may comprise two or more of those skeletons in combination, and polysiloxane molecules having different two or more structures can be employed in mixture.

The polysiloxane compound of the present invention preferably comprises a repeating unit represented by the following formula (I) or (II).

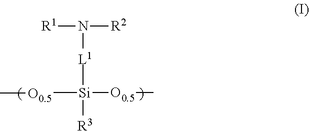

In the above formula,
L¹ is an alkylene group having 1 to 20 carbon atoms or an arylene group having 6 to 20 carbon atoms,
each of R¹ and R² is independently hydrogen atom, an alkyl group which has 1 to 12 carbon atoms and which may have a nitrogen-containing substituent, or an aryl group which has 6 to 12 carbon atoms and which may have a nitrogen-containing substituent, and
R³ is hydrogen atom, hydroxyl group, an alkyl group which has 1 to 12 carbon atoms and which may have a nitrogen-containing substituent, an aryl group having 6 to 12 carbon atoms, or an alkoxy group which has 1 to 12 carbon atoms and which may have a nitrogen-containing substituent.

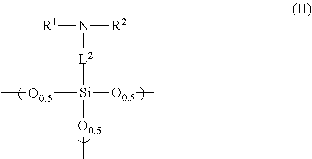

In the above formula,
L² is an alkylene group having 1 to 20 carbon atoms or an arylene group having 6 to 20 carbon atoms, and
each of R⁴ and R⁵ is independently hydrogen atom, an alkyl group which has 1 to 12 carbon atoms and which may have a nitrogen-containing substituent, or an aryl group which has 6 to 12 carbon atoms and which may have a nitrogen-containing substituent.
In the present invention, the term “nitrogen-containing substituent” means a substituent group containing a nitrogen atom in its structure. Examples thereof include amino groups, amide groups, nitro groups, imide bond-containing groups, and amide bond-containing groups. The nitrogen-containing substituent may have the same structure as —L¹—NR¹R² in the formula (I). Among the above, amino groups, monoalkyl-substituted amino groups, and dialkyl-substituted amino groups are preferred in the present invention.

Examples of L¹ in the formula (I) include methylene, ethylene, trimethylene, phenylene, naphthalenediyl, and anthracenediyl. The compound having trimethylene as L¹ is particularly preferred because raw material monomers thereof are easily available and highly stable in storage.

Examples of R¹ and R² in the formula (I) include hydrogen, methyl, ethyl, n-propyl, iso-propyl, t-butyl, phenyl, aminoethyl, 1,3-dimethyl-butylidene, and vinylbenzyl. The compound in which R¹ and R² are both hydrogen atoms is particularly preferred because raw material monomers thereof are easily available and also because it can be produced without the need for any complicated procedures.

Examples of R³ in the formula (I) include hydrogen, hydroxyl, methyl, ethyl, propyl, phenyl, and aminoalkyl. The compound having hydroxyl as R³ is particularly preferred because raw material monomers thereof are formed by hydrolysis of alkoxy groups.

Examples of the polysiloxane compound comprising a repeating unit represented by the formula (I) include: N-(2-aminoethyl)-3-aminopropylsiloxane, 3-aminopropylsiloxane, N-(1.3-dimethyl-butylidenepropyl-siloxane, N-phenyl-3-aminopropylsiloxane, 3-ureido-propylmethylsiloxane. Among them, N-(2-aminoethyl)-3-aminopropylsiloxane and 3-aminopropyl-siloxane are preferred because they are easily available.

Examples of L² in the formula (II) include methylene, ethylene, trimethylene, cyclohexylene, and phenylene. The compound having trimethylene as L² is particularly preferred because raw material monomers thereof are easily available and highly stable in storage.

Examples of R⁴ and R⁵ in the formula (II) include hydrogen, methyl, ethyl, n-propyl, iso-propyl, t-butyl, phenyl, aminoethyl, 1,3-dimethyl-butylidene, and vinylbenzyl. The compound in which R⁴ and R⁵ are both hydrogen atoms is particularly preferred because raw material monomers thereof are easily available and also because it can be produced without the need for any complicated procedures.

Examples of the polysiloxane compound comprising a repeating unit represented by the formula (II) include:
N-(2-aminoethyl)-3-aminopropylsilsesquioxane,
N-(1.3-dimethyl-butylidenepropylsilsesquioxane,
N-phenyl-3-aminopropylsilsesquioxane, and amino-propylsilsesquioxane. Among them, aminopropylsilsesquioxane is particularly preferred because raw material monomers thereof are easily available.

The polysiloxane compound comprising a repeating unit represented by the formula (II) preferably has a Si₈O₁₂ structure in which Si atoms are positioned at the vertices of a hexahedron and each adjacent two thereof are connected to each other by way of an oxygen atom. However, even if the hexahedral structure is partly cleaved to form a polysiloxane compound having a structure in which the repeating unit of the formula (II) is combined with that of the formula (I), the formed compound can be also employed in the composition according to the present invention.

The polysiloxane compound of the present invention has a weight average molecular weight of normally 200 to 100000, preferably 300 to 10000, more preferably 300 to 5000. Here, the “weight average molecular weight” means weight average molecular weight in terms of polystyrene according to gel permeation chromatography.

(B) solvent

The composition according to the present invention contains a solvent. The composition of the present invention is generally applied directly on a resist pattern, and hence preferably gives no effect to the resist layer. Specifically, the composition preferably does not impair the pattern shape. Accordingly, it is preferred to adopt an aqueous solvent comprising a large amount of water, which hardly affects the resist layer. Typically, water is used as the solvent. When used as the aqueous solvent, water is preferably beforehand subjected to purification, such as, distillation, ion-exchange treatment, filtration treatment or various adsorption treatments, so as to remove organic impurities, metal ions and the like.

The amount of the polysiloxane compound in the composition is controlled according to the purpose, but is generally 0.1 to 30 wt %, preferably 1 to 10 wt % based on the total weight of the composition. It should be noticed that the composition may largely absorb extreme UV light if containing the polysiloxane compound too much.

In order to improve solubility of the components in the composition, the above aqueous solvent may contain an organic solvent in as small an amount as 30 wt % or less based on the total weight thereof. Examples of the organic solvent usable in that mixed solvent include: (a) hydrocarbons, such as, n-hexane, n-octane and cyclohexane; (b) alcohols, such as, methyl alcohol, ethyl alcohol and isopropyl alcohol; (c) ketones, such as, acetone and methyl ethyl ketone; (d) esters, such as, methyl acetate, ethyl acetate and ethyl lactate; (e) ethers, such as, diethyl ether and dibutyl ether; and (f) other polar solvents, such as, dimethylformamide, dimethyl sulfoxide, methyl cellosolve, cellosolve, butyl cellosolve, cellosolve acetate, alkylcellosolve acetate, butyl carbitol and carbitol acetate. Any of them can be used according to the purpose. Among the above, alcohols having 1 to 20 carbon atoms, such as, methyl alcohol, ethyl alcohol and isopropyl alcohol are preferred because they hardly affect the resist.

The composition of the present invention necessarily comprises the above (A) and (B), but can further comprise optional additives in combination. Those additional components will be described below. The total amount of the components other than (A) or (B) is preferably 10% or less, more preferably 5% or less, based on the total weight of the composition.

Examples of the optional additives include surfactant, acid and base. Those should be employed as long as the kinds and amounts thereof are appropriately selected so as not to impair the effect of the present invention.

The surfactant is used for the purposes of ensuring homogeneity of the composition and of improving coating properties thereof. In order to make the surfactant fully work for improving surface roughness of the formed resist layer, the content of the surfactant is preferably 50 to 100000 ppm, more preferably 50 to 50000 ppm, further preferably 50 to 20000 ppm, based on the total weight of the composition. It should be noted that, if the composition contains the surfactant too much, problems such as development failure may occur.

The acid or base is employed for the purposes of controlling the pH value of the composition and of improving solubility of each component. The acid or base can be freely selected as long as it does not impair the effect of the invention. For example, carboxylic acids, amines and ammonium salts are employable. Those acids and bases include aliphatic acids, aromatic acids, primary amines, secondary amines, tertiary amines and ammonium compounds. They may be substituted with any substituents. Examples thereof include: formic acid, acetic acid, propionic acid, benzoic acid, phthalic acid, salicylic acid, lactic acid, malic acid, citric acid, oxalic acid, malonic acid, succinic acid, fumaric acid, maleic acid, aconitic acid, glutaric acid, adipic acid, monoethanolamine, diethanolamine, triethanolamine, triisopropanolamine, and tetramethyl-ammonium.

The composition according to the present invention may further contain germicide, antibacterial agent, preservative, and/or anti-mold agent. Those chemicals are added for the purpose of preventing bacteria or fungi from propagating in the composition with the passage of time. Examples thereof include alcohols, such as phenoxyethanol, and isothiazolone. Specifically, for example, Bestside ([trademark], manufactured by Nippon Soda Co., Ltd.) can serve as particularly effective preservative, anti-mold agent or germicide. Those chemicals typically give no effect to the function of the composition, and are contained in an amount of normally 1% or less, preferably 0.1% or less, more preferably 0.001% or less, based on the total weight of the composition.

Pattern Formation Method

The pattern formation method of the present invention will be described below. The following is a typical process in which the surface treatment composition of the invention is employed according to the pattern formation method.

First, a photosensitive resin composition is applied on a surface, which may be pretreated if necessary, of a substrate, such as a silicon or glass substrate, according to a known coating method such as spin-coating method, to form a photosensitive resin layer. Prior to applying the photosensitive resin composition, an antireflective coating may be beforehand formed thereunder on the substrate surface. The antireflective coating makes it possible to improve the sectional shape and the exposure margin.

In the pattern formation method according to the present invention, any known photosensitive resin composition can be adopted. Typical examples of the photosensitive resin composition employable in the pattern formation method of the present invention are as follows: positive-working type compositions, such as, a composition comprising a quinonediazide photosensitizer and an alkali-soluble resin, and a chemically amplified photosensitive resin composition; and negative-working type compositions, such as, a composition containing a polymer compound having photosensitive groups (e.g., polycinnamic acid vinyl), a composition containing an aromatic azide compound, a composition containing an azide compound (e.g., cyclized rubber-bisazide compound), a compound containing a diazo resin, a photopolymerizable composition containing an addition polymerizable unsaturated compound, and a chemically amplified negative-working photosensitive resin composition.

In the above positive-working composition comprising a quinonediazide photosensitizer and an alkali-soluble resin, the quinonediazide photosensitizer is, for example, 1,2-benzoquinonediazide-4-sulfonic acid, 1,2-naphthoquinonediazide-4-sulfonic acid, 1,2-naphtho-quinonediazide-5-sulfonic acid, or an ester or amide thereof. Examples of the alkali-soluble resin include novolac resin, polyvinylphenol, polyvinyl alcohol, and copolymers of acrylic or methacrylic acid. The novolac resin is preferably produced from one or more phenols, such as, phenol, o-cresol, m-cresol, p-cresol and xylenol, in combination with one or more aldehydes, such as, formamide and paraformamide.

Any chemically amplified photosensitive resin composition, such as, a positive-working one, a negative-working one or a negative-working resist for organic development, can be employed in the pattern formation method of the present invention. The chemically amplified resist generates an acid when exposed to UV radiation, and the acid serves as a catalyst to promote chemical reaction by which solubility to the developing solution is changed within the areas irradiated with the UV radiation to form a pattern. For example, the chemically amplified resist composition comprises an acid-generating compound, which generates an acid when exposed to UV radiation, and an acid-sensitive functional group-containing resin, which decomposes in the presence of acid to form an alkali-soluble group such as phenolic hydroxyl or carboxyl group. The composition may comprise an alkali-soluble resin, a crosslinking agent and an acid-generating compound.

The photosensitive resin composition layer formed on the substrate is then prebaked, for example, on a hot plate to remove the solvent contained in the composition, so as to form a resist layer having a thickness of normally about 0.03 to 10 μm. The prebaking temperature depends on the substrate and the solvent, but is normally 20 to 200° C., preferably 50 to 150° C.

The resist layer is then subjected to exposure through a mask, if necessary, by means of known exposure apparatus such as a high-pressure mercury lamp, a metal halide lamp, an ultra-high pressure mercury lamp, a KrF excimer laser, an ArF excimer laser, a soft X-ray irradiation system, and an electron beam lithography system.

After the exposure, post exposure baking (PEB) is carried out, if necessary. Subsequently, development such as puddle development is carried out to form a resist pattern. The resist is normally developed with an alkali developer, which is, for example, an aqueous solution of potassium hydroxide, tetramethylammonium hydroxide (TMAH) or tetrabutyl-ammonium hydroxide (TBAH). If the composition layer is formed from a negative-working resist for organic development, the resist is developed with a developer of organic solvent, such as, n-butyl acetate (nBA) or methyl n-amyl ketone (MAK). After the development, the resist pattern is rinsed (washed) with a rinse solution. The thus formed pattern is adopted as a resist for etching, plating, ion diffusion or dyeing, and thereafter peeled away, if necessary.

Thereafter, the surface treatment composition according to the present invention is brought into contact with the resist pattern by coating or the like so that the pattern surface may be covered with the composition, to form a covering layer. Before coated with the composition, the developed resist pattern is preferably washed with pure water or the like. Further, also before coated with the composition, the resist pattern may be dried to remove the water or solvent swelling the pattern and/or the surface thereof. However, the resist pattern may be coated without being dried after developed or washed. If intended to be dried, the resist pattern may be subjected to drying treatment successively after developed or washed and then further successively coated with the composition (to form a covering layer). For the purpose of actively removing the water or solvent in the resist pattern, the drying treatment can be carried out, for example, by heating or blowing dry gas over the pattern. Specifically, the resist pattern can be heated at 30 to 70° C. for 10 to 300 seconds. Further, examples of the gas usable in the blow dry treatment include air and inert gases, such as, nitrogen and argon. On the other hand, if intended to be coated without being dried, the resist pattern can be coated with the composition successively after developed or washed. The resist pattern is generally not actively dried after developed or washed. However, the resist pattern may be dried after developed or washed, then stored or transported, and thereafter separately coated with the composition of the present invention in another independent step.

The resist pattern coated with the covering layer is then baked (mixing-bake procedure), and thereby the component of the covering layer soaks into the resist pattern to cause a reaction near the interface between the resist resin layer and the covering layer. As a result of the reaction, acid on the resist pattern surface is combined by hydrogen bonds with amino groups of the siloxane polymer to form a layer by which the resist surface is modified into a siliceous surface. Finally, the resist surface is rinsed with water or solvents to remove an unreacted portion of the surface treatment composition, to obtain a surface-modified resist pattern.

In the pattern formation method of the present invention, the composition can be applied by any coating method, such as spin coating method, slit coating method, spray coating method, dip coating method or roller coating method. Those methods have been conventionally adopted for applying resist resin compositions. If necessary, the formed covering layer can be baked.

The covering layer is subjected to heat treatment (mixing-bake treatment) according to necessity. If needed, the treatment is carried out at a temperature of 40 to 200° C., preferably 5 to 100° C., for 10 to 300 seconds, preferably 30 to 120 seconds. The thickness of the formed covering layer can be properly controlled according to the temperature and time of the heat treatment and to the kind of the adopted resist resin composition. The covering layer generally has a thickness of 0.001 to 0.5 μm from the surface thereof immediately after the composition is applied.

Thereafter, an excess of the surface treatment composition is subjected to washing treatment with a cleaning solution, and then the covering layer is preferably dried. The cleaning solution is preferably the same as the solvent of the composition, that is, for example, pure water. Subsequently, if necessary, the formed pattern is post-baked.

In the resist pattern thus obtained, the polysiloxane compound near the surface is mostly modified into silicon. Accordingly, the resist pattern according to the present invention has high etching resistance and low solubility in solvents.

The present invention will be further explained by examples described below.

### synthesis of Polysiloxane compound 1: preparation of 3-aminopropylsiloxane

In a 500 ml-flask, 100 ml of 3-aminopropyltriethoxysilane was placed. While the flask was cooled in an ice bath, 100 ml of pure water was dropwise added into the flask from a dropping funnel so slowly that it took 10 minutes to finish the addition. After a product formed in the flask was stirred for 30 minutes, the flask was taken out of the ice bath and then the product was further stirred for 1 hour at room temperature. Subsequently, by-produced ethanol was removed from the product at 60° C. under a reduced-pressure condition (30 Torr, 1 hour), to obtain Polysiloxane compound 1. The content of the product was measured by weight reduction method after water was evaporated in an oven. As a result, the yield was found to be 54%. The molecular weight of the product was also measured by GPC, and thereby it was found that the number and weight average molecular weights were 1178 and 1470, respectively, in terms of polystyrene.

### synthesis of Polysiloxane compound 2: preparation of N-(2-aminoethyl)-3-aminopropylsiloxane

In a 500 ml-flask, 100 ml of N-(2-aminoethyl)-3-aminopropyltri-ethoxysilane was placed. While the flask was cooled in an ice bath, 100 ml of pure water was dropwise added into the flask from a dropping funnel so slowly that it took 10 minutes to finish the addition. After a product formed in the flask was stirred for 30 minutes, the flask was taken out of the ice bath and then the product was further stirred for 1 hour at room temperature. Subsequently, by-produced ethanol was removed from the product at 60° C. under a reduced-pressure condition (30 Torr, 1 hour), to obtain Polysiloxane compound 2. The content of the product was measured by weight reduction method after water was evaporated in an oven. As a result, the yield was found to be 47%. The molecular weight of the product was also measured by GPC, and thereby it was found that the number and weight average molecular weights were 1530 and 1968, respectively, in terms of polystyrene.

### synthesis of Polysiloxane compound 3: preparation of 3-aminopropylsilsesquioxane

In a 1000 ml-flask, 0.25 mol of 3-aminopropyltriethoxysilane, 0.77 mol of Me₄NOH and 500 ml of methanol as a solvent were placed and made to react under a nitrogen atmosphere so as to synthesize octa3-aminopropylsilsesquioxane. The synthesis reaction was conducted at room temperature for 24 hours and then at 60° C. for 24 hours. Subsequently, after excesses of Me₄NOH and water were removed, the residue was kept at 110° C. for 24 hours. Finally, the residue was purified with 100 ml of hexane and 100 ml of toluene, to obtain Polysiloxane compound 3. The yield was found to be 92.7%. The molecular weight of the purified product was measured by GPC, and thereby it was found that the number and weight average molecular weights were 817 and 817, respectively, in terms of polystyrene.

In 100 ml of a solvent, 5 g of Polysiloxane compound obtained above was dissolved and stirred at room temperature for 3 hours. Thus, a composition of Example 101 for forming a covering layer was produced. The procedure was repeated except for changing the components into those shown in Table 1, to produce compositions of Examples 102, 103 and Comparative examples 101, 102 for forming covering layers.

TABLE 1

| | | Components | |
|---|---|---|---|
| | Composition | Polysiloxane compound | Solvent |
| Ex. 101 | Composition 1 | Polysiloxane compound 1 | water |
| Ex. 102 | Composition 2 | Polysiloxane compound 2 | water |
| Ex. 103 | Composition 3 | Polysiloxane compound 3 | water |
| Com. 101 | Composition 4 | methylsiloxane (weight | water |
| | | average MW: 1500) | |
| Com. 102 | Composition 5 | phenylsiloxane (weight | n-butanol |
| | | average MW: 700) | |

Evaluation of Coating Properties

The following three substrates were prepared, and then Composition 1 was applied thereon and baked at 60° C. for 60 seconds, to produce samples of Example 201. The coating properties were visually evaluated to obtain the results shown in Table 2. Subsequently, the procedure was repeated except for changing the composition into those shown in Table 2, to obtain the results of Examples 202, 203 and Comparative examples 201, 202.

Substrate 1: a silicon substrate;

Substrate 2: a resist layer-provided substrate prepared in the manner in which a silicon substrate was spin-coated with ArF photoresist composition (AX1120P [trademark], manufactured by Merck Performance Materials Ltd.) at 2000 rpm and then baked at 100° C. for 110 seconds to form thereon a resist layer of 12 μm thickness; and

Substrate 3: a developed resist substrate prepared in the manner in which a Substrate 2 was subjected to exposure at 26 mJ with ArF exposure apparatus (NSR-S306C [trademark], manufactured by Nikon Corporation), then heated at 100° C. for 110 seconds, successively developed at 23° C. for 120 seconds in a 2.38% TMAH aqueous solution, and finally rinsed with deionized water to form thereon a 1:1 line-and-space pattern of 0.12 μm width.

TABLE 2

| | Composition | Substrate 1 | Substrate 2 | Substrate 3 |
|---|---|---|---|---|
| Ex. 201 | Composition 1 | A | A | A |
| Ex. 202 | Composition 2 | A | A | A |
| Ex. 203 | Composition 3 | A | A | A |
| Com. 201 | Composition 4 | A | B | B |
| Com. 202 | Composition 5 | C | B | B |

The evaluation grades in the table mean the following.

A: The composition formed a homogeneous layer.

B: The composition formed a layer on which some uneven parts were observed.

C: The composition failed to form a layer.

Evaluation of Etching Resistance

Composition 1 was applied on a Substrate 2 and then baked at 60° C. for 60 seconds to form a covering layer, so that a sample of Example 301 was produced. The sample was subjected to oxygen plasma etching in a dry etching apparatus (NE5000N [trademark], manufactured by ULVAC, Inc.) with a mixed gas of O₂ and N₂ (flow ratio: O_{2/}N₂=30/70) under the conditions of: pressure: 0.67 Pa, RF: 100 w, temperature: 25° C., and processing time: 15 seconds, to measure the etching rate. In the same manner as Example 301, the compositions shown in Table 3 were applied to form covering layers and then the etching rates were individually measured. The results are shown in Table 3.

TABLE 3

| | | Etching rate |
|---|---|---|
| | Composition for forming a covering layer | (nm/s) |
| Ex. 301 | Composition 1 | 0.6 |
| Ex. 302 | Composition 2 | 0.6 |
| Ex. 303 | Composition 3 | 0.5 |
| Com, 301 | Composition 4 | 0.6 |
| Com, 302 | Composition 5 | 0.9 |
| Com, 303 | absent (only the resist layer) | 7.2 |
| Com, 304 | absent (only an undercoat layer) | 4.1 |

The undercoat layer was a carbon underlayer formed from AZ U98-85 ([trademark], manufactured by Merck Performance Materials Ltd.).

Evaluation of Covering Layer-Formation on Positive Resist Pattern

A composition for forming an antireflective underlayer (AZ ArF 1C5D [trademark], manufactured by Merck Performance Materials Ltd.) was applied by a spin-coater, and then baked at 200° C. for 60 seconds to form an underlayer of 37 nm thickness. Subsequently, a resist composition (AX1120P [trademark], manufactured by Merck Performance Materials Ltd.) was further applied thereon by a spin-coater at 2000 rpm, and then baked at 100° C. for 110 seconds to form a resist layer of 120 nm thickness. The formed resist layer was subjected to exposure at 26 mJ with ArF exposure apparatus (NSR-S306C [trademark], manufactured by Nikon Corporation), then heated at 100° C. for 110 seconds, successively developed at 23° C. for 120 seconds in a 2.38% TMAH aqueous solution, and finally rinsed with deionized water, to obtain a developed resist substrate provided with a 1:1 line-and-space pattern of 120 nm width.

The pattern-provided resist substrate thus obtained was spin-coated at 1500 rpm with each component shown in Table 4, then subjected to mixing-bake treatment under the conditions shown in Table 4, subsequently washed with a cleaning solution shown in Table 4, and finally post-baked at 110° C. for 60 seconds, to obtain each of the samples of Examples 401, 402 and Comparative examples 401, 402. The obtained substrates were puddled with PGMEA for 60 seconds, and spin-dried. Thereafter, the sections of the substrates were observed with SEM (S-4700 [trademark], manufactured by Hitachi High-Technologies Corporation). Both after the resist pattern was formed and after the mixing pattern was formed in the above procedure, it was independently confirmed that each substrate was provided with a pattern thereon.

The evaluation grades in the table mean the following.

A: The pattern was confirmed to remain almost the same as immediately after the mixing pattern was formed.

B: The pattern changed in that the space width shrunk by 5% or more as compared with the width immediately after the mixing pattern was formed.

C: No pattern was observed. This is presumed to be because the resist pattern was not covered and hence dissolved in PGMEA.

TABLE 4

| | | Mixing-bake | Cleaning | Evaluation |
|---|---|---|---|---|
| | Composition | conditions | solution | grade |
| Ex. 401A | Composition 1 | not baked | pure water | A |
| Ex. 401B | Composition 1 | 60° C., | pure water | A |
| | | 60 seconds | | |
| Ex. 402A | Composition 2 | not baked | pure water | A |
| Ex. 402B | Composition 2 | 60° C., | pure water | A |
| | | 60 seconds | | |
| Com. 401A | Composition 4 | not baked | n-butanol | C |
| Com. 401B | Composition 4 | 100° C., | n-butanol | C |
| | | 60 seconds | | |
| Com. 402A | Composition 5 | not baked | n-butanol | C |
| Com. 402B | Composition 5 | 100° C., | n-butanol | C |
| | | 60 seconds | | |

Evaluation of Covering Layer-Formation on Negative Resist Pattern

A composition for forming an antireflective underlayer (AZ ArF 1C5D [trademark], manufactured by Merck Performance Materials Ltd.) was applied by a spin-coater, and then baked at 200° C. for 60 seconds to form an underlayer of 37 nm thickness. Subsequently, a resist composition (AX1120P NTD [trademark], manufactured by Merck Performance Materials Ltd.) was further applied thereon by a spin-coater at 2000 rpm, and then baked at 100° C. for 110 seconds to form a resist layer of 120 nm thickness. The formed resist layer was subjected to exposure at 20 mJ with ArF exposure apparatus (NSR-S306C [trademark], manufactured by Nikon Corporation), then subjected to post-exposure heating at 120° C. for 60 seconds, and successively developed for 100 seconds with methyl n-amyl ketone (MAK), to obtain a developed resist substrate provided with a 1:1 line-and-space pattern of 120 nm width.

The pattern-provided resist substrate thus obtained was spin-coated at 1500 rpm with each component shown in Table 5, then subjected to mixing-bake treatment under the conditions shown in Table 5, subsequently washed with a cleaning solution shown in Table 5, and finally post-baked at 110° C. for 60 seconds, to obtain each of the samples of Examples 501, 502, 503 and Comparative examples 501, 502. The obtained substrates were puddled with PGMEA for 60 seconds, and spin-dried. Thereafter, the sections of the substrates were observed with SEM (S-4700 [trademark], manufactured by Hitachi High-Technologies Corporation). Both after the resist pattern was formed and after the mixing pattern was formed in the above procedure, it was independently confirmed that each substrate was provided with a pattern thereon.

TABLE 5

| | | Mixing-bake | Cleaning | Evaluation |
|---|---|---|---|---|
| | Composition | conditions | solution | grade |
| Ex. 501A | Composition 1 | not baked | pure water | A |
| Ex. 501B | Composition 1 | 60° C., | pure water | A |
| | | 60 seconds | | |
| Ex. 502A | Composition 2 | not baked | pure water | A |
| Ex. 502B | Composition 2 | 60° C., | pure water | A |
| | | 60 seconds | | |
| Ex. 503 | Composition 3 | 80° C., | pure water | A |
| | | 60 seconds | | |
| Com. 501A | Composition 4 | not baked | n-butanol | B |
| Com. 501B | Composition 4 | 100° C., | n-butanol | B |
| | | 60 seconds | | |
| Com. 502A | Composition 5 | not baked | n-butanol | B |
| Com. 502B | Composition 5 | 100° C., | n-butanol | B |
| | | 60 seconds | | |

The evaluation grades in the table mean the same as the above.

Evaluation of Etching Resistance on Resist Pattern

A resist composition (AX1120P [trademark], manufactured by Merck Performance Materials Ltd.) was applied on a silicon substrate by a spin-coater at 2000 rpm, and then baked at 100° C. for 110 seconds to form a resist layer of 120 nm thickness. The formed resist layer was subjected to exposure at 10 mJ with ArF exposure apparatus (NSR-S306C [trademark], manufactured by Nikon Corporation), then heated at 100° C. for 110 seconds, successively developed at 23° C. for 100 seconds in a 2.38% TMAH aqueous solution, and finally rinsed with deionized water, to form a 10 mm×10 mm semi-open pattern.

The pattern-provided resist substrate thus obtained was spin-coated at 1500 rpm with each component shown in Table 6, and then washed with a cleaning solution shown in Table 6, to obtain each of the samples of Examples 601 to 603 and Comparative examples 601, 602. Each sample was subjected to oxygen plasma etching in a dry etching apparatus (NE5000N [trademark], manufactured by ULVAC, Inc.) with a mixed gas of O₂ and N₂ (flow ratio: O₂/N₂=30/70) under the conditions of: pressure: 0.67 Pa, RF: 100 w, temperature: 25° C., and processing time: 15 seconds, to measure the etching rate. The results are shown in Table 6.

TABLE 6

| | | | Etching rate |
|---|---|---|---|
| | Composition | Cleaning solution | (nm/s) |
| Ex. 601 | Composition 1 | pure water | 1.5 |
| Ex. 602 | Composition 2 | pure water | 1.8 |
| Ex. 603 | Composition 3 | pure water | 1.2 |
| Com. 601 | Composition 4 | n-butanol | 3.8 |
| Com. 602 | Composition 5 | n-butanol | 4.4 |

1.-14. (canceled)

15. A resist pattern surface treatment composition comprising a solvent and a polysiloxane compound soluble in said solvent,
wherein a silicon atom which is constituent atom of said polysiloxane connects to a nitrogen-substituted hydrocarbon group provided that said silicon atom directly binds to a carbon atom in said hydrocarbon group.

16. The composition according to claim 15, wherein said polysiloxane compound comprises a repeating unit represented by the following formula (I) or (II): 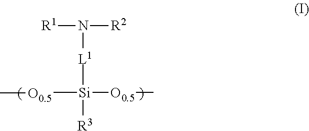
in which
L¹ is an alkylene group having 1 to 20 carbon atoms or an arylene group having 6 to 20 carbon atoms,
each of R¹ and R² is independently hydrogen atom, an alkyl group which has 1 to 12 carbon atoms and which may have a nitrogen-containing substituent, or an aryl group which has 6 to 12 carbon atoms and which may have a nitrogen-containing substituent, and
R³ is hydrogen atom, hydroxyl group, an alkyl group which has 1 to 12 carbon atoms and which may have a nitrogen-containing substituent, an aryl group having 6 to 12 carbon atoms, or an alkoxy group which has 1 to 12 carbon atoms and which may have a nitrogen-containing substituent; 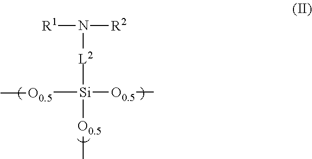
in which
L² is an alkylene group having 1 to 20 carbon atoms or an arylene group having 6 to 20 carbon atoms, and
each of R⁴ and R⁵ is independently hydrogen atom, an alkyl group which has 1 to 12 carbon atoms and which may have a nitrogen-containing substituent, or an aryl group which has 6 to 12 carbon atoms and which may have a nitrogen-containing substituent.

17. The composition according to claim 16, wherein said R¹ and R² are both hydrogen atoms or said R⁴ and R⁵ are both hydrogen atoms.

18. The composition according to claim 16, wherein said L¹ or L² is selected from trimethylene, N-(2-aminoethyl)-3-aminopropyl, or phenylene.

19. The composition according to claim 16, wherein said polysiloxane compound comprises a repeating unit represented by the formula (II) and has a Si₈O₁₂ structure in which Si atoms are positioned at the vertices of a hexahedron and each adjacent two thereof are connected to each other by way of an oxygen atom.

20. The composition according to claim 16, wherein said R³ is hydroxyl group.

21. The composition according to claim 15, wherein said solvent is water.

22. The composition according to claim 15, wherein said polysiloxane compound has a weight average molecular weight of 200 to 100000.

23. A surface treatment method for a developed resist pattern, which comprises the step of bringing the surface of a developed resist pattern into contact with the composition according to claim 15.

24. A pattern formation method comprising the steps of:
coating a substrate with a resist composition, to form a resist composition layer;
exposing said resist composition layer to light;
developing the exposed resist composition layer with a developer, to form a resist pattern;
bringing the surface of said resist pattern into contact with the composition according to claim 15, to form a covering layer; and
removing an excess of said composition by washing treatment.

25. The method according to claim 24, wherein the resist pattern is formed and then dried before the covering layer is formed thereon.

26. The method according to claim 24, wherein the resist pattern is formed with the developer and thereafter the covering layer is formed without the resist pattern being dried.

27. The method according to claim 24, which further comprises the step of carrying out heating treatment after the covering layer is formed but before the washing treatment is carried out.

28. The method according to claim 27, wherein said heating treatment is carried out at a heating temperature of 40 to 200° C.
